(19) United States
(12) Patent Application Publication
(10) Pub. No.: US 2009/0260976 A1
(43) Pub. Date: Oct. 22, 2009

(54) MAGNETRON SPUTTERING APPARATUS AND PRODUCTION METHOD OF THIN FILM

(75) Inventor: Noboru Nakamura, Kawasaki-shi (JP)

Correspondence Address: FITZPATRICK CELLA HARPER & SCINTO, 30 ROCKEFELLER PLAZA, NEW YORK, NY, 10112, US

(73) Assignee: CANON ANELVA CORPORATION, Kawasaki-shi (JP)

(21) Appl. No.: 12/420,524

(22) Filed: Apr. 8, 2009

(30) Foreign Application Priority Data
Apr. 18, 2008 (JP) 2008-109080

(51) Int. Cl. C23C 14/35

(52) U.S. Cl. 204/192.15; 204/298.07

(57) ABSTRACT

To form a LaB₆ thin film by magnetron sputtering, a target 11 is applied with DC power and high-frequency component power having a low-frequency component filtered out from a high-frequency power source 193, and a substrate holder 13 is applied with DC power from another DC power source 221 during the application of the high-frequency component power and the DC power. Thus, monocrystallinity in a large-area domain direction of the obtained LaB₆ thin film is improved.

### BACKGROUND OF THE INVENTION

The present invention relates to a production apparatus of a boron-lanthanum compound thin film containing boron and lanthanum atoms and a production method of the thin film.

As described in Japanese Patent Laid-open Publications No. 286228/1989, No. 232959/1991 and No. 101033/1991, there is conventionally known a thin film of a boron-lanthanum compound such as LaB₆ as a secondary electron generation film. The conventional inventions described in the above three publications form a monocrystalline thin film of a boron-lanthanum compound by a sputtering method.

### BRIEF SUMMARY OF THE INVENTION

But, when the boron-lanthanum compound thin film formed by the conventional sputtering apparatus and sputtering method is applied to a secondary electron source film, its electron generation efficiency is not satisfactory as the secondary electron source film.

Especially, in a case where the thin film formed of a boron-lanthanum compound such as LaB₆ is used for FED (Field Emission Display) or SED (Surface-Conduction Electron-emitter Display), satisfactory brightness has not been obtained for the display device at present.

According to the study conducted by the present inventor, the above disadvantage results from the point that the thin film formed of the boron-lanthanum compound has insufficient crystal growth. Especially, if the film has a very small thickness of 10 nm or below, monocrystallinity is not sufficient in a large-area domain direction, and a large-area domain is not formed due to a crystal grain boundary.

It was found by the study conducted by the present inventor that the improvement of the monocrystallinity in the large-area domain direction can substantially improve the secondary electron generation efficiency, and especially, brightness of the electron generating device such as FED or SED can be improved. The improvement of brightness reduces the anode voltage of the FED or SED and also leads to the enlargement of a usable range of a usable phosphor or its selection range at the same time.

The present invention provides a production apparatus capable of improving monocrystallinity in a large-area domain direction to form a thin film composed of a boron-lanthanum compound such as LaB₆, and its production method.

A first magnetron sputtering apparatus according to the present invention comprises a first chamber, an exhaust device for vacuum exhausting the inside of the chamber, a cathode capable of attaching a target configured of a boron-lanthanum compound containing boron and lanthanum atoms, and a high-frequency power source for applying high-frequency power to the cathode. It also has a first DC power source for applying DC power to the cathode during the application of the high-frequency power, a magnetic field generation device for exposing the surface of the target to a magnetic field, a first substrate holder for holding a substrate at a position opposed to the cathode, and a second DC power source for applying DC power to the first substrate holder.

A second magnetron sputtering apparatus according to the present invention omits the second DC power source from the first magnetron sputtering apparatus and provides a filter for filtering out a low-frequency component from a high-frequency power source for applying high-frequency power to the cathode.

A third magnetron sputtering apparatus according to the present invention provides the first magnetron sputtering apparatus with a filter for filtering out a low-frequency component from a high-frequency power source for applying high-frequency power to the cathode.

A preferable embodiment of the first and third magnetron sputtering apparatuses according to the present invention has pulse waveform power as the DC power from the second DC power source. The pulse waveform preferably has a waveform having a phase opposite to the phase of the low-frequency component from the high-frequency power source.

A preferable embodiment of the first through third magnetron sputtering apparatuses according to the present invention further comprises an annealing unit which is provided with a second chamber, a device for generating at least one of ions, electrons or active species within the second chamber, a second substrate holder for holding the substrate, and a heating device for heating the substrate. In an embodiment having the above annealing unit, it is preferable that either or both are satisfied between a state that the first chamber and the second chamber are connected in a state capable of keeping their insides in a vacuum state (decompressed state) and a state of having a third DC power source for applying DC power to the second substrate holder.

A fourth magnetron sputtering apparatus according to the present invention is additionally provided with a second high-frequency power source for applying high-frequency power to the substrate holder independent of the high-frequency power source (first high-frequency power source) for applying high-frequency power to the cathode in the first magnetron sputtering apparatus.

A fifth magnetron sputtering apparatus according to the present invention is additionally provided with a second high-frequency power source for applying high-frequency power to the substrate holder independent of the high-frequency power source (first high-frequency power source) for applying high-frequency power to the cathode in the third magnetron sputtering apparatus.

A sixth magnetron sputtering apparatus according to the present invention is additionally provided with a second high-frequency power source for applying high-frequency power to the substrate holder, and a second filter for filtering out a low-frequency component from the second high-frequency power source independent of the high-frequency power source (first high-frequency power source) for applying high-frequency power to the cathode and the filter (first filter) for filtering out the low-frequency component from the first high-frequency power source in the third magnetron sputtering apparatus.

A production method of a first thin film according to the present invention comprises forming a boron-lanthanum compound thin film on a substrate held by a substrate holder in a vacuum exhausted atmosphere by a magnetron sputtering method using a target composed of a boron-lanthanum compound containing boron and lanthanum atoms, wherein the target is applied with high-frequency component power resulting from filtering out a low-frequency component from a high-frequency power source and first DC power from a first DC power source, and the substrate holder is applied with second DC power from a second DC power source during the application of the high-frequency component power and DC power.

According to the production method of a first thin film of the present invention, the second DC power is preferably pulse waveform power, and the boron-lanthanum compound is preferably a stoichiometric or nonstoichiometric LaB₆.

A preferable embodiment of the production method of a first thin film according to the present invention further comprises heating the boron-lanthanum compound thin film, and exposing to at least one of atmospheres of ions, electrons or active species during, after or before the heating.

Another preferable embodiment of the production method of the first thin film according to the present invention further comprises heating the boron-lanthanum compound thin film, and exposing to at least one of atmospheres of ions, electrons or active species under application of a direct electric field during, after or before the heating.

A production method of a second thin film according to the present invention comprises forming a boron-lanthanum compound thin film on a substrate held by a substrate holder in a vacuum exhausted atmosphere by a magnetron sputtering method using a target composed of a boron-lanthanum compound containing boron and lanthanum atoms, wherein the target is applied with high-frequency component power and first DC power from first DC power source, and the substrate holder is applied with second DC power from a second DC power source during the application of the high-frequency component power and DC power.

According to the present invention, the secondary electron generation efficiency by the thin film composed of the boron-lanthanum compound such as LaB₆ is improved. And, brightness of the FED or SED display device using the thin film as the secondary electron source film can be improved.

### BRIEF DESCRIPTION OF THE SEVERAL VIEWS OF THE DRAWINGS

FIG. 1 is a sectional view of the magnetron sputtering apparatus according to a first example of the present invention.

FIG. 2 is a schematic sectional view of the electron generating device of the present invention.

FIG. 3A and FIG. 3B are enlarged sectional views of LaB₆ thin films, FIG. 3A is the LaB₆ thin film of the present invention, and FIG. 3B is a LaB₆ thin film not according to the present invention.

FIG. 4 is a sectional view of the vertical in-line magnetron sputtering apparatus according to a second example of the present invention.

FIG. 5 is a sectional view of the magnetron sputtering apparatus according to a third example of the present invention.

### DETAILED DESCRIPTION OF THE INVENTION

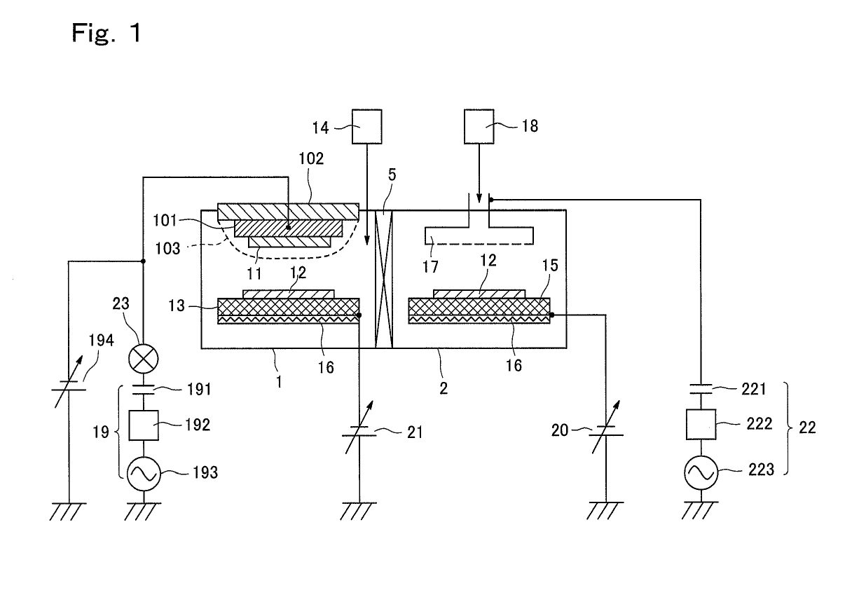

FIG. 1 is a schematic view of the apparatus according to a first example of the present invention. Reference numeral 1 is a first chamber, 2 is a second chamber (annealing unit) vacuum-connected to the first chamber 1, 3 is a substrate charging chamber, 4 is a discharging chamber, 5 is a gate valve, 11 is a target using a boron-lanthanum compound such as LaB₆, 12 is a substrate, 13 is a substrate holder (first substrate holder) for holding the substrate 12, 14 is a sputtering gas feed system, 15 is a substrate holder (second substrate holder), 16 is a heating mechanism, 17 is a plasma electrode, 18 is a gas feed system for a plasma source, 19 is a sputtering high-frequency power source system, 101 is a cathode capable of attaching the target 11 configured of a boron-lanthanum compound containing boron and lanthanum atoms, 102 is a magnetic field generation device, 103 is a magnetic-field region, 191 is a blocking capacitor, 192 is a matching circuit, 193 is a high-frequency power source, 194 is a sputtering bias power source, 20 is a (annealing) substrate bias power source, 21 is a substrate bias power source (second DC Power source), 22 is a high-frequency power source system for a plasma source, 221 is a blocking capacitor, 222 is a matching circuit, 223 is a high-frequency power source, and 23 is a low-frequency cut filter (first filter) which filters out a low-frequency component from the high-frequency power source 193 to provide high-frequency component power.

The substrate 12 is placed on the first holder 13 in the first chamber 1 to face the cathode 101, and the inside of the chamber is vacuum exhausted and heated (increased up to a temperature for sputtering to be performed later). Heating is performed by the heating mechanism 16. Then, sputtering gas (argon gas, krypton gas, xenon gas) is introduced from the sputtering gas feed system 14 to set a prescribed pressure (0.01 Pa to 50 Pa, and preferably 0.1 Pa to 10 Pa), and the sputtering power source 19 is used to start forming a film.

Subsequently, high-frequency power (frequency of 0.1 MHz to 10 GHz, and preferably 1 MHz to 5 GHz, and applied power of 100 W to 3000 W, and preferably 200 W to 2000 W) is applied from the high-frequency power source 193 to generate plasma, and DC power (voltage) is set by the first DC power source 194 to a prescribed voltage (−50 V to −1000V, and preferably −100 V to −500V), and sputtering film formation is performed. On the substrate 12 side, DC power (voltage) is applied to the first substrate holder 13 at a prescribed voltage (−10 V to −1000V, and preferably −100 V to −500V) by the second DC power source 21. DC power (first DC power) from the first DC power source 194 may be applied before the application of high-frequency power from the high-frequency power source 193, may be applied simultaneously when the high-frequency power is applied or may also be applied continuously even after the application of the high-frequency power is completed.

Positions where DC power and/or high-frequency power is applied from the second DC power source 21 and/or the sputtering high-frequency power source 19 to the first substrate holder 13 are preferably plural points which are symmetrical to the center point of the first substrate holder 13. For example, the symmetric positions to the center point of the first substrate holder 13 can be determined to be the application positions of plural DC power and/or high-frequency power.

The magnetic field generation device 102 made of a permanent magnet or an electromagnet is arranged to position behind the cathode 101, so that the surface of the target 11 can be exposed to the magnetic field 103. It is desirable that the magnetic field 103 does not reach the surface of the substrate 12, but the magnetic field 103 may reach the surface of the substrate 12 if its level does not narrow the large-area monocrystalline domain of the boron-lanthanum compound film.

The S and N poles of the magnetic field generation means 102 can be arranged to mutually have a reverse polarity in a perpendicular direction with respect to the plane surface of the cathode 103. It is determined that the adjacent magnets have a reverse polarity mutually in a horizontal direction with respect to the plane surface of the cathode 103.

The S and N poles of the magnetic field generation means 102 can also be arranged to have a reverse polarity mutually in a horizontal direction with respect to the plane surface of the cathode 103. In this case, the adjacent magnets are also determined to mutually have a reverse polarity in a horizontal direction with respect to the plane surface of the cathode 103.

In a preferable embodiment of the present invention, the magnetic field generation means 102 can perform an oscillating movement in a horizontal direction with respect to the plane surface of the cathode 103.

The first filter 23 used in the present invention can filter out a low-frequency component (frequency component of 0.01 MHz or less, and particularly 0.001 MHz or less) from the high-frequency power source 193. A monocrystalline domain size is variable apparently depending on whether or not the first filter 23 is used. When the first filter 23 is used, the monocrystalline domain has an average area of 1 μm² to 1 mm², and preferably 5 μm² to 500 μm², and when the first filter 23 is not used, the monocrystalline domain has an average area of 0.01 μm² to 1 μm².

In addition, the present invention can increase the average area of the monocrystalline domain by application of the DC power (voltage) from the second DC power source 21 on the substrate 12 side. This second DC power source 21 (voltage) may be pulse waveform power having a DC component (DC component to the ground) in time average.

The present invention can also increase the average area of the monocrystalline domain by adding an annealing process.

After the film formation is completed by the magnetron sputtering method described above, the substrate 12 is conveyed into the second chamber 2 via the gate valve 5 while keeping the vacuum state, the substrate 12 is placed on the second holder 15 in the second chamber 2, and annealing (200° C. to 800° C. and preferably 300° C. to 500° C.) is started by the heating mechanism 16. When annealing is performed, plasma from a plasma source gas (argon gas, krypton gas, xenon gas, hydrogen gas, nitrogen gas or the like) is irradiated to the substrate 12 by the gas feed system 18 for the plasma source, and a prescribed voltage (−10 V to −1000V, and preferably −100 V to −500V) may be applied by the second DC power source 21. After the annealing is completed, the inside of the second chamber 2 is returned to the atmosphere, and the substrate 12 is removed.

Besides, the power source system 22 for the plasma source is provided with the blocking capacitor 221, the matching circuit 222 and the high-frequency power source 223, and high-frequency power (frequency of 0.1 MHz to 10 GHz, and preferably 1 MHz to 5 GHz, and power of 100 W to 3000 W, and preferably 200 W to 2000 W) can be applied from the high-frequency power source 223.

The second substrate holder 15 is heated to a prescribed temperature by the heating mechanism 16, and the substrate 12 placed on the second substrate holder 15 is undergone the annealing treatment. Here, the preset temperature and annealing treatment time of the heating mechanism 16 are adjusted to optimum values depending on the required film properties. At this time, annealing effect can be enhanced furthermore by irradiating a particle beam of ions, electrons, radicals (active species) or the like by the substrate 12. The irradiation of the particle beam of ions, electrons, radicals (active species) or the like can be performed during, after or before the substrate 12 is heated.

In this example, an example of the plasma source using the parallel plate type high-frequency discharge electrode 17 (plasma electrode 17) is described, but a bucket type ion source, an ECR (electron cyclotron resonance) ion source, an electron beam irradiation device or the like can also be used. The second substrate holder 15 on which the substrate 12 is placed may have a floating electrical potential, but it is also effective to apply a prescribed bias voltage from the second DC power source 21 in order to have the energy of the incident particles at a prescribed level. The substrate 12 having undergone the annealing treatment is removed into the atmosphere through an unshown conveying chamber, conveying mechanism, and charging and discharging chambers. After forming the LaB₆ thin film, this apparatus performs the annealing treatment and others without removing the substrate 12 into the atmosphere, so that the LaB₆ surface is not contaminated by the components contained in the atmosphere. Thus, the LaB₆ thin film having a good crystal structure can be obtained.

The present invention can form the LaB₆ film which is a stoichiometric thin film by using a target of stoichiometric composition.

According to another example of the present invention, a nonstoichiometric thin film can be formed by a simultaneous sputtering method using a stoichiometric LaB₆ target and an La target.

The LaB₆ thin film used in the present invention can also contain other components such as Ba metal and the like.

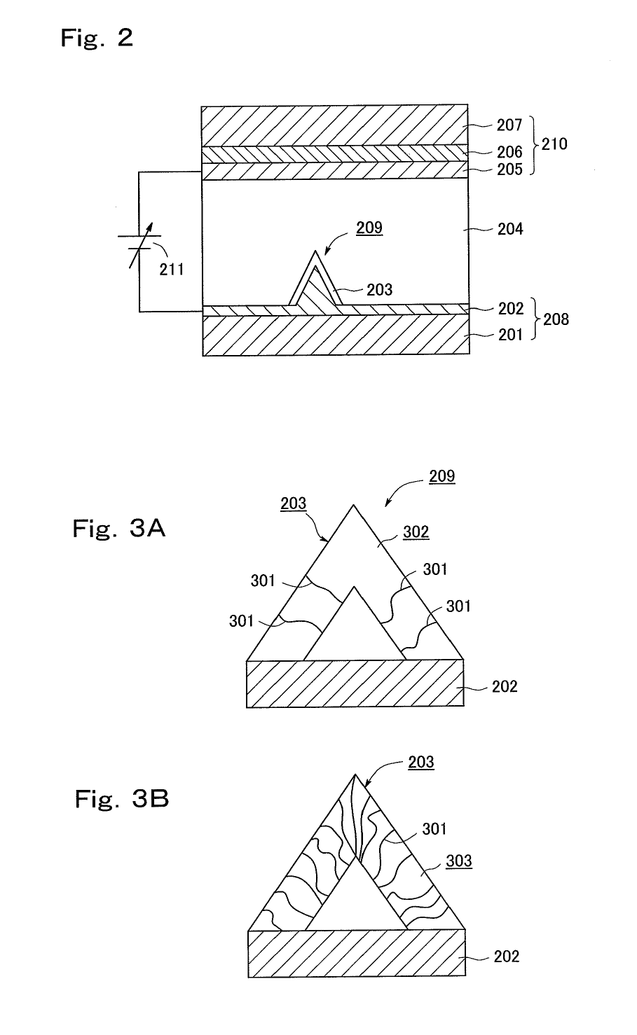

In FIG. 2, 208 is an electron source substrate having a molybdenum film (cathode electrode) 202 which forms a cone shaped projection 209 and an LaB₆ film 203 which covers a projection 209 of the molybdenum film. Reference numeral 210 is a phosphor substrate which is composed of a glass substrate 207, a phosphor film 206 formed on it, and an anode electrode 205 made of a thin aluminum film. A space 204 between the electron source substrate 208 and the phosphor substrate 210 is a vacuum space. ADC voltage of 100 Vto 3000 Vis applied to between the cathode electrode 202 and the anode electrode 205 to emit an electron beam from the tip end of the projection 209 of the molybdenum film 202 covered with the LaB₆ film 203 toward the anode electrode 205. The electron beam is transmitted through the anode electrode 205 to hit the phosphor film, and fluorescence can be produced.

FIG. 3A and FIG. 3B are enlarged sectional views of the projection 209 covered with the LaB₆ film 203 of FIG. 2. The projection 209 of FIG. 3A is covered with the LaB₆ film 203 formed according to the present invention, and a monocrystalline large-area domain 302 which is surrounded by a crystal grain boundary 301 is formed in the film. The monocrystalline large-area domain 302 has an average area of 1 μm² to 1 mm², and preferably 5 μm² to 500 μm². The projection 209 of FIG. 3B is covered with the LaB₆ film 203 which is formed not according to the present invention, and a monocrystalline small-area domain 303 is formed in the film. This monocrystalline small-area domain 303 has an average area of 0.01 μm² to 1 μm².

Then, the electron generating device shown in FIG. 2 is produced, and its brightness is visually observed and judged. The judged results are shown in Table 1 below.

The electron source substrate 208 was produced by forming the molybdenum film 202 having a thickness of 3 μm and the projection 209 having a cone radius of 1 μm and a height of 2 μm on the glass substrate 201 and then forming the LaB₆ film 203 having a thickness of 5 nm by a magnetron bias sputtering method.

To form the LaB₆ film 202 used here, the use of DC power from the first DC power source 194 (−250V) and the second DC power source 21 (−100V) and the use of the filter were changed as shown in Table 1 below. A frequency of 13.56 MHz and 800 W were used for the high-frequency power source 193.

The electron generating device has a vacuum chamber configured of the electron source substrate 208, the phosphor substrate 210 having the anode electrode 205 and a 2 mm thick seal member (not shown). And the anode electrode 205 and the cathode electrode 202 are connected to a 500 Volt DC power source 211.

TABLE 1

| | | Brightness |
|---|---|---|
| | | observed |
| | Type of power source | results |
| Example 1 | First DC power source | Very bright |
| | 194 used | Suitable for |
| | Second DC power source | displaying |
| | 21 used | |
| | First filter 23 used | |
| Example 2 | First DC power source | Bright but not |
| | 194 used | very |
| | Second DC power source | Suitable for |
| | 21 used | displaying |
| | First filter 23 not used | |
| Example 3 | First DC power source | Bright enough |
| | 194 used | in comparison |
| | Second DC power source | with Example 2 |
| | 21 not used | Suitable for |
| | (Floating state | displaying |
| | maintained) | |
| | First filter 23 used | |
| Comp. Exam. | First DC power source | Dark |
| | 194 used | Not suitable |
| | Second DC power source | for displaying |
| | 21 not used | |
| | (Floating state | |
| | maintained) | |
| | First filter 23 not used | |

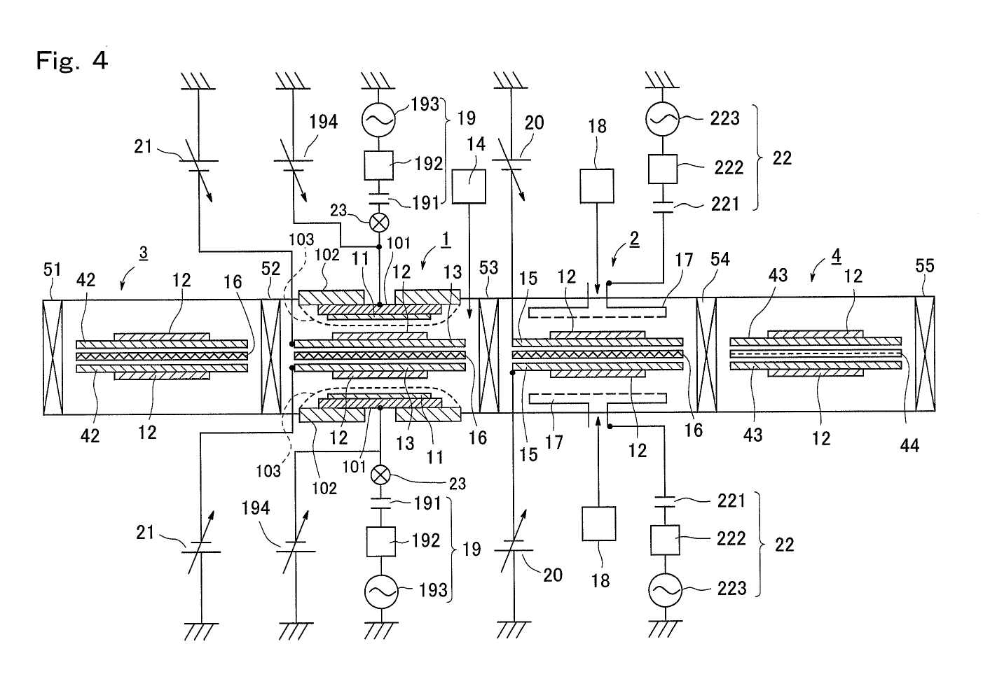

The apparatus shown in FIG. 4 is an example of a vertical in-line sputtering apparatus according to a second example of the present invention and shown as a sectional view of the apparatus viewed from the above. Like reference numerals as those of FIG. 1 denote like parts or corresponding parts.

Two substrates 12 are fixed to two substrate holders 42, respectively, conveyed together with the substrate holders 42 from the atmosphere side into a charging chamber 3 via a gate valve 51 and then treated. When a tray (not shown) is conveyed into the charging chamber 3, the gate valve 51 is closed, and the inside of the chamber is evacuated by an unshown exhaust system. When evacuated to a prescribed pressure or below, a gate valve 52 to a first chamber 1 is opened, the tray is conveyed into the first chamber 1, and the gate valve 52 is closed. Then, the LaB₆ thin film is formed in the same manner as described in the first example, and the sputtering gas is exhausted in the same manner as in the first example. After the exhaustion to a prescribed pressure, a gate valve 53 to the second chamber 2 is opened, and the tray is conveyed into the second chamber 2. The heating mechanism 16 kept at a prescribed temperature is arranged within the second chamber 2, and the substrates 12 can be undergone the annealing treatment together with the second substrate holders 15. At this time, electrons, ions, radicals or the like may be used in the same manner as in the example shown in FIG. 1. After completing the annealing, the inside of the chamber is evacuated, a gate valve 54 to a discharging chamber 4 is opened, the tray is conveyed into the discharging chamber 4, and the substrates 12 are fixed to substrate holders 43. Then, the gate valve 54 is closed. The discharging chamber 4 is provided with a cooling panel 44 for lowering the substrate temperature after the annealing. After lowering to a prescribed temperature, the inside of the discharging chamber 4 is returned to the atmosphere pressure by leak gases (nitrogen gas, hydrogen gas, argon gas or the like), and a gate valve 55 is opened to remove the tray into the atmosphere.

In this example, the tray is treated in a stationary state in the first chamber 1 and the second chamber 2 but may be treated while moving. In such a case, the first chamber 1 and the second chamber 2 may be added as required in order to balance with speed up of the treating speed of the apparatus as a whole.

As a magnetron sputtering method, the method using both the high-frequency power and the DC power at the same time was described above. But, magnetron sputtering may be performed by the first DC power source 194 without application of a high frequency depending on the film quality required. This case has an advantage that the high-frequency power source 193 and the matching circuit 192 are unnecessary, and the apparatus cost can be reduced.

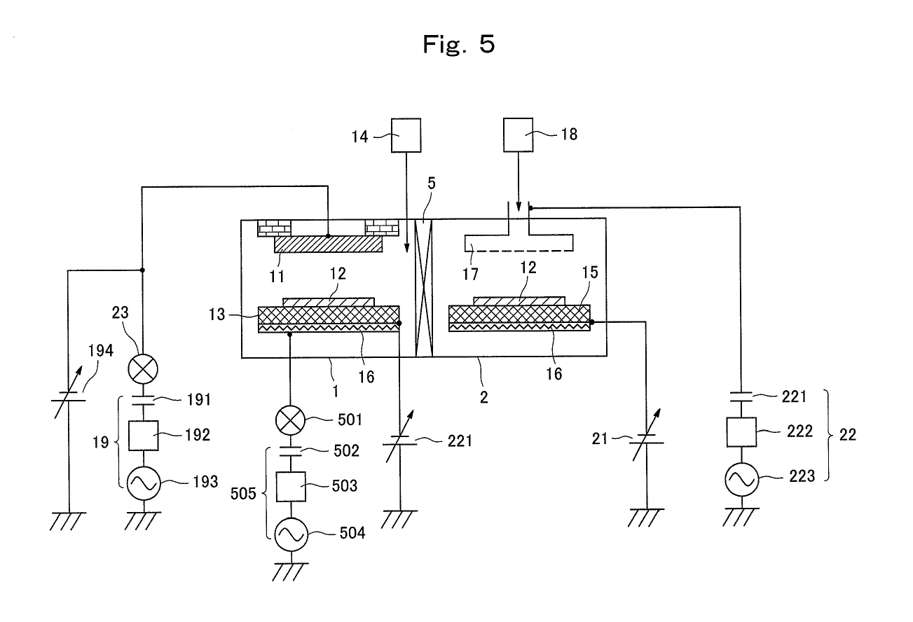

FIG. 5 is a schematic view of the apparatus according to a third example of the present invention. The apparatus of this example is configured with a high-frequency power source system 505 for a substrate added to the apparatus of FIG. 1. The high-frequency power source system 505 for a substrate is used to apply high-frequency power to the substrate 12 through the substrate holder 13.

The sputtering high-frequency power source system 19 in this example is provided with the blocking capacitor 191, the matching circuit 192 and the high-frequency power source (first high-frequency power source) 193 in the same manner as the apparatus of FIG. 1. And, the sputtering high-frequency power source system 19 is connected to the first filter 23 which filters out the low-frequency component from the first high-frequency power source 193.

The high-frequency power source system 505 for a substrate added in this example is provided with a blocking capacitor 502, a matching circuit 503 and a high-frequency power source (second high-frequency power source) 504. And, the high-frequency power source system 505 for a substrate is connected to a filter (second filter) 501 which filters out a low-frequency component from the second high-frequency power source 504.

The high-frequency power source system 505 for a substrate outputs high-frequency power (frequency of 0.1 MHz to 10 GHz, and preferably 1 MHz to 5 GHz, and applied power of 100 Wto 3000 W, and preferably 200 Wto 2000 W) from the second high-frequency power source 504, and can apply high-frequency power from the blocking capacitor 502, the matching circuit 503 and the second high-frequency power source 504 to the substrate 12 through the second filter 501 which filters out a low-frequency component. The use of the second filter 501 may be omitted.

The electron generating device produced by the apparatus shown in FIG. 5 could achieve brightness far brighter than the phosphor brightness achieved by the example 1.

According to the present invention, the magnet unit used for magnetron sputtering can be a generally used permanent magnet.

In a case where the magnetron sputtering is performed after the tray is stopped from moving, a target having an area slightly larger than the substrate 12 is provided, and a plurality of magnet units are arranged on the back surface of the target with an appropriate space among them and caused to make translational movement in a direction parallel to the surface of the target. Thus, good thickness uniformity and high coefficient of utilization of the target can be obtained. In a case where the sputtering is performed while moving the tray, a target having a width smaller than the length of the substrate and a magnet unit can be used for the moving direction of the substrate 12.

The preferable embodiments and examples of the present application have been described with reference to the accompanying drawings, but the present invention is not limited to the embodiments and examples described above. It is to be understood that modifications and variations can be made without departing from the spirit and scope of the invention.

1. A magnetron sputtering apparatus, comprising:
a first chamber,
an exhaust device for vacuum exhausting the inside of the chamber,
a cathode capable of attaching a target configured of a boron-lanthanum compound containing boron and lanthanum atoms,
a high-frequency power source for applying high-frequency power to the cathode,
a first DC power source for applying DC power to the cathode during the application of the high-frequency power,
a magnetic field generation device for exposing the surface of the target to a magnetic field,
a first substrate holder for holding a substrate at a position opposed to the cathode, and
a second DC power source for applying DC power to the first substrate holder.

2. A magnetron sputtering apparatus, comprising:
a first chamber,
an exhaust device for vacuum exhausting the inside of the chamber,
a cathode capable of attaching a target configured of a boron-lanthanum compound containing boron and lanthanum atoms,
a high-frequency power source for applying high-frequency power to the cathode,
a first DC power source for applying DC power to the cathode during the application of the high-frequency power,
a filter for filtering out a low-frequency component from the high-frequency power source,
a magnetic field generation device for exposing the surface of the target to a magnetic field, and
a first substrate holder for holding a substrate at a position opposed to the cathode.

3. A magnetron sputtering apparatus, comprising:
a first chamber,
an exhaust device for vacuum exhausting the inside of the chamber,
a cathode capable of attaching a target configured of a boron-lanthanum compound containing boron and lanthanum atoms,
a high-frequency power source for applying high-frequency power to the cathode,
a first DC power source for applying DC power to the cathode during the application of the high-frequency power,
a filter for filtering out a low-frequency component from the high-frequency power source,
a magnetic field generation device for exposing the surface of the target to a magnetic field,
a first substrate holder for holding a substrate at a position opposed to the cathode, and
a second DC power source for applying DC power to the first substrate holder.

4. The magnetron sputtering apparatus according to claim 1 wherein the second DC power is pulse waveform power.

5. The magnetron sputtering apparatus according to claim 1, further comprising:
an annealing unit which is provided with a second chamber, a device for generating at least one of ions, electrons or active species within the second chamber, a second substrate holder for holding the substrate, and a heating device for heating the substrate.

6. The magnetron sputtering apparatus according to claim 5, wherein the first chamber and the second chamber are connected in a state capable of keeping their insides in a vacuum state.

7. The magnetron sputtering apparatus according to claim 5, further comprising a third DC power source for applying DC power to the second substrate holder.

8. The magnetron sputtering apparatus according to claim 1, wherein the boron-lanthanum compound is stoichiometric or nonstoichiometric LaB₆.

9. A magnetron sputtering apparatus, comprising:
a first chamber,
an exhaust device for vacuum exhausting the inside of the chamber,
a cathode capable of attaching a target configured of a boron-lanthanum compound containing boron and lanthanum atoms,
a first high-frequency power source for applying high-frequency power to the cathode,
a first DC power source for applying DC power to the cathode during the application of the high-frequency power,
a magnetic field generation device for exposing the surface of the target to a magnetic field,
a substrate holder for holding a substrate at a position opposed to the cathode,
a second DC power source for applying DC power to the substrate holder, and
a second high-frequency power source for applying high-frequency power to the substrate holder.

10. A magnetron sputtering apparatus, comprising:
a first chamber,
an exhaust device for vacuum exhausting the inside of the chamber,
a cathode capable of attaching a target configured of a boron-lanthanum compound containing boron and lanthanum atoms,
a first high-frequency power source for applying high-frequency power to the cathode,
a first DC power source for applying DC power to the cathode during the application of the high-frequency power,
a filter for filtering out a low-frequency component from the first high-frequency power source,
a magnetic field generation device for exposing the surface of the target to a magnetic field,
a substrate holder for holding a substrate at a position opposed to the cathode,
a second DC power source for applying DC power to the substrate holder, and
a second high-frequency power source for applying high-frequency power to the substrate holder.

11. A magnetron sputtering apparatus, comprising:
a first chamber,
an exhaust device for vacuum exhausting the inside of the chamber,
a cathode capable of attaching a target configured of a boron-lanthanum compound containing boron and lanthanum atoms,
a first high-frequency power source for applying high-frequency power to the cathode,
a first DC power source for applying DC power to the cathode during the application of the high-frequency power,
a first filter for filtering out a low-frequency component from the first high-frequency power source,
a magnetic field generation device for exposing the surface of the target to a magnetic field,
a substrate holder for holding a substrate at a position opposed to the cathode,
a second DC power source for applying DC power to the substrate holder,
a second high-frequency power source for applying high-frequency power to the substrate holder, and
a second filter for filtering out a low-frequency component from the second high-frequency power source.

12. A production method of a thin film, comprising:
forming a boron-lanthanum compound thin film on a substrate held by a substrate holder in a vacuum exhausted atmosphere by a magnetron sputtering method using a target composed of a boron-lanthanum compound containing boron and lanthanum atoms, wherein:
the target is applied with high-frequency component power resulting from filtering out a low-frequency component from a high-frequency power source and first DC power from a first DC power source, and
the substrate holder is applied with second DC power from a second DC power source during the application of the high-frequency component power and DC power.

13. The production method of a thin film according to claim 12, wherein the second DC power is pulse waveform power.

14. The production method of a thin film according to claim 12, wherein the boron-lanthanum compound is stoichiometric or nonstoichiometric LaB₆.

15. The production method of a thin film according to claim 12, further comprising:
heating the boron-lanthanum compound thin film, and exposing to at least one of atmospheres of ions, electrons or active species during, after or before the heating.

16. The production method of a thin film according to claim 12, further comprising:
heating the boron-lanthanum compound thin film, and exposing to at least one of atmospheres of ions, electrons or active species under application of a direct electric field during, after or before the heating.

17. A production method of a thin film, comprising:
forming a boron-lanthanum compound thin film on a substrate held by a substrate holder in a vacuum exhausted atmosphere by a magnetron sputtering method using a target composed of a boron-lanthanum compound containing boron and lanthanum atoms, wherein:
the target is applied with high-frequency component power and first DC power from first DC power source, and
the substrate holder is applied with second DC power from a second DC power source during the application of the high-frequency component power and DC power.
